(19) United States
(12) Patent Application Publication
(10) Pub. No.: US 2025/0031469 A1
(43) Pub. Date: Jan. 23, 2025

(54) LIGHT-ABSORBING STRUCTURE AND PHOTODETECTOR HAVING THE SAME

(71) Applicant: National Taiwan University, Taipei (TW)

(72) Inventors: Ching-Fuh Lin, Taipei (TW); Kun-Rong Lin, Taipei (TW)

(21) Appl. No.: 18/383,835

(22) Filed: Oct. 25, 2023

(30) Foreign Application Priority Data
Jul. 21, 2023 (TW) 112127270

(51) Int. Cl. H01L 27/146; G02B 5/00

(52) U.S. Cl. CPC H01L 27/14625; G02B 5/003; G02B 5/008; H01L 27/14685

(57) ABSTRACT

A light-absorbing structure includes a metal layer composed an inverted truncated-pyramid structure (ITPS) array to absorb an incident light especially in the infrared band. A cross-section of each inverted truncated-pyramid structure includes an upper base and a lower base, where the length of the upper base is greater than the length of the lower base. A photo detector includes a semiconductor layer, the mentioned metal layer, a first electrode, and a second electrode. An upper surface of the semiconductor layer includes an ITPS array and forms a Schottky contact with the metal layer. The first electrode contacts with an upper surface of the metal layer, and the second electrode forms Ohmic contact with a lower surface of the semiconductor layer.

### CROSS-REFERENCE TO RELATED APPLICATIONS

The entire contents of Taiwan Patent Application No. 112127270, filed on Jul. 21, 2023, from which this application claims priority, are expressly incorporated herein by reference.

### BACKGROUND OF THE INVENTION

### 1. Field of the Invention

The present invention relates to a light-absorbing structure and a photodetector includes the light-absorbing structure.

### 2. Description of Related Art

The development of science and technology makes life more convenient. Among them, infrared light-sensing has been applied in many aspects—e.g.: observing space stars, analyzing material composition, night visioning, and measuring human physiological characteristics, etc.

Current infrared sensors mostly employ semiconductors with small energy gaps such as III-V or Ge as the active layer or detection-absorbing material to detect infrared light with a small photon energy. Although existing III-V or Ge-based detectors have been well-established in their manufacturing process, these materials are more expensive than others, and the process requires many complex and expensive epitaxial devices. The principle of such devices is mostly mid bandgap absorption (MBA). Carriers in the semiconductor are excited by incident light and surpass the semiconductor bandgap to generate photocurrents. In order to improve the detection efficiency or the responsivity of the device, such components often need to incorporate complex multiple quantum wells (MQWs) or multiple quantum dots (MQDs) in the active layer. For these reasons, infrared photodetectors are not common.

U.S. patent (US2019348564A1) previously filed by applicant discloses a photo detector having a metal/semiconductor junction with a mechanism different from the MBA to detect infrared light, and the photo detector is produced in an easy and low-cost manner. In addition, previous studies had proposed different microstructure arrays on the surface of semiconductor to enhance the surface plasmon resonance and confine the incident light deep in the microstructure. The microstructures form cavities with each containing multiple linear cavity lengths, and a wavelength of the incident light corresponds to one of the linear cavity lengths to induce a localized surface plasmon resonance. Such that all regions of the cavities can induce the localized surface plasmon resonance (LSPR) for different wavelengths of the incident light, including the visible and near-infrared wavelength bands.

Another applicant's previously filed Taiwan patent (App. No. 11121205550) continued the previous study. Pre-processing and/or post-processing, e.g., adding an insulating layer between metal and semiconductor, are performed on the photodetector to improve the signal readability and the signal-to-noise ratio (SNR). The as-fabricated photo detector has a response time of less than 10 microseconds.

### SUMMARY OF THE INVENTION

This summary is provided to introduce a selection of concepts in a simplified form that are further described below in the detailed description. This summary, and the foregoing background, is not intended to identify key aspects or essential aspects of the claimed subject matter. Moreover, this summary is not intended for use as an aid in determining the scope of the claimed subject matter.

In one aspect, a light-absorbing structure is provided with a metal layer composed of an inverted truncated-pyramid structure (ITPS) array to absorb an incident light. A cross-section of each inverted truncated-pyramid structure of the ITPS array comprises an upper base and a lower base, and a length of the upper base is greater than a length of the lower base.

In some embodiments, the thickness of the metal layer is approximately 10 nm. In some embodiments, a bottom surface of each inverted truncated-pyramid structure comprises the lower base, and the bottom surface is hollow. In some embodiments, a ratio of a central wavelength of the incident light to the length of the lower base is between 1.09 and 1.24. In some embodiments, a ratio of the length of the upper base to the length of the lower base is between 0.312 and 0.4545. In some embodiments, an absorption of the light-absorbing structure is less than 50% for the incident light in the wavelength range of 360 nm to 830 nm.

In another aspect, a photodetector is provided with a semiconductor, a metal layer, a first electrode, and a second electrode. The semiconductor layer includes an inverted truncated-pyramid structure (ITPS) array. The metal layer forms Schottky contact with a surface of the ITPS array. The first electrode contacts with an upper surface of the metal layer. The second electrode forms ohmic contact with a lower surface of the semiconductor layer. A cross-section of each inverted truncated-pyramid structure of the ITPS array comprises an upper base and a lower base, and a length of the upper base is greater than a length of the lower base. Carriers in the metal layer or the semiconductor layer are excited by an incident light to form hot carriers crossing a junction between the metal layer and the semiconductor layer to generate a photocurrent.

Through the design of ITPS, the provided light-absorbing structure and photodetector increase the responses for incident light with a specific wavelength band. In addition, the provided light-absorbing structure and photodetector can be made of easily available materials and highly compatible manufacturing processes, thereby reducing the costs and allowing them to be widely used in daily life.

### BRIEF DESCRIPTION OF THE DRAWINGS

Non-limiting and non-exhaustive embodiments of the disclosed technology, including the preferred embodiment, are described with reference to the following figures, wherein like reference numerals refer to like parts throughout the various views unless otherwise specified.

FIG. 1 shows a photodetector according to an embodiment of the present invention.

FIGS. 2A and 2B are top view and cross-sectional SEM photos of the photodetector fabricated according to an embodiment of the present invention.

FIG. 3A and FIG. 3B show the relationship between incident power and response current/responsivity of the fabricated photodetector having IPS (base length 14 μm) on the silicon surface, and the measurements are made with different filters 3.46, 4.26, 5.3, 6.0 μm between and the incident light and the photodetector.

FIG. 4A and FIG. 4B show the relationship between incident power and response current/responsivity of the fabricated photodetector having ITPS (upper base 14 μm/lower base 5 μm) on the silicon surface, and the measurements are made with different filters 3.46, 4.26, 5.3, 6.0 μm between and the incident light and the photodetector.

FIG. 5 shows the relationship between the wavelengths of incident light and the response currents of a photodetector having IPS (with a period/base 14 μm) and a photodetector having ITPS (with period/upper base 14 μm and lower base 5 μm), where the incident light is emitted from an incandescent lamp applied with a constant voltage of 30V.

FIGS. 6A and 6B show the incident power versus response current/responsivity of the photodetector with ITPS (upper base 16 μm/lower base 5 μm) on the silicon surface, and the measurements are made with different filters (3.46 μm, 4.26 μm, 5.3 μm) between and the incident light and the photodetector.

FIGS. 6C and 6D show the incident power versus response current/responsivity of the photodetector with ITPS (upper base 16 μm/lower base 5 μm) on the silicon surface, and the measurements are made with different filters (5.3 μm, 6.0 μm, 7.0 μm) between and the incident light and the photodetector.

FIG. 7 shows the relationship between the wavelengths of incident light and the response currents of a photodetector having IPS (with a period/lower base 16 μm) and a photodetector having ITPS (with period/upper base 16 μm and lower base 5 μm), where the incident light is emitted from an incandescent lamp applied with a constant voltage of 30V.

FIG. 8A and FIG. 8B show the relationship between incident power and response voltage/responsivity of the fabricated photodetector having IPS (base 14 μm) on the silicon surface, and the response voltages/responsivities are measured by a phase-locked system with an incandescent lamp as the light source and different filters (3.46, 4.26, 5.3, 6.0, 7.0 μm) between and the incident light and the photodetector.

FIG. 9A and FIG. 9B show the relationship between incident power and response voltage/responsivity of the fabricated photodetector having ITPS (upper base 14 μm/lower base 5 μm) on the silicon surface, and the response voltages/responsivities are measured by a phase-locked system with an incandescent lamp as the light source and different filters (3.46, 4.26, 5.3, 6.0, 7.0 μm) between and the incident light and the photodetector.

FIG. 10A and FIG. 10B show the relationship between incident power and response voltage/responsivity of the fabricated photodetector having IPS (base 16 μm) on the silicon surface, and the response voltages/responsivities are measured by a phase-locked system with an incandescent lamp as the light source and different filters (3.46, 4.26, 5.3, 6.0, 7.0 μm) between and the incident light and the photodetector.

FIG. 11A and FIG. 11B show the relationship between incident power and response voltage/responsivity of the fabricated photodetector having ITPS (upper base 16 μm/lower base 5 μm) on the silicon surface, and the response voltages/responsivities are measured by a phase-locked system with an incandescent lamp as the light source and different filters (3.46, 4.26, 5.3, 6.0, 7.0 μm) between and the incident light and the photodetector.

FIG. 12A shows the relationship between the wavelengths of incident light and response voltages of the photodetector having IPS (with a period/base 14 μm) and the photodetector having ITPS (with period/upper base 14 μm and lower base 5 μm), and the response voltages are measured by a phase-locked system with an incandescent lamp as the light source and different filters between and the incident light and the photodetector.

FIG. 12B shows the relationship between the wavelengths of incident light and response voltages of the photodetector having IPS (with a period/base 16 μm) and the photodetector having ITPS (with period/upper base 16 μm and lower base 5 μm), and the response voltages are measured by a phase-locked system with an incandescent lamp as the light source and different filters between and the incident light and the photodetector.

FIG. 13A and FIG. 13B respectively show the relationship between wavelengths of the incident light and the response current/the simulated electric field intensity of the photodetector with ITPS (upper base/lower base 14/5 μm) and the photodetector with IPS (lower base 14 μm).

FIG. 13C and FIG. 13D respectively show the relationship between wavelengths of the incident light and the response current/the integrated electric field intensity of the photodetector with ITPS (upper base/lower base 16/5 μm) and the photodetector with IPS (lower base 16 μm).

FIG. 14A and FIG. 14B respectively show the relationship between wavelengths of the incident light and the response current/the integrated simulated electric field intensity of the photodetector with ITPS (upper base/lower base 14/5 μm) and the photodetector with IPS (base 14 μm).

FIG. 14C and FIG. 14D respectively show the relationship between wavelengths of the incident light and the response current/the integrated simulated electric field intensity of the photodetector with ITPS (upper base/lower base 16/5 μm) and the photodetector with IPS (base 16 μm).

FIGS. 15A to 15D illustrate a manufacturing method wherein the bottom surface of an inverted truncated-pyramid structure is free of the metal layer.

### DETAILED DESCRIPTION OF THE PREFERRED EMBODIMENT

Embodiments are described more fully below with reference to the accompanying Figures, which form a part hereof and show, by way of illustration, specific exemplary embodiments. These embodiments are disclosed in sufficient detail to enable those skilled in the art to practice the invention. However, embodiments may be implemented in many different forms and should not be construed as being limited to the embodiments set forth herein. The following detailed description is, therefore, not to be taken in a limiting sense.

The previous application (US2019348564A1) had fabricated photodetectors having inverted pyramid structure array with periods of 4 μm, 6 μm, and 8 μm, which reveal good response currents in the visible and near-infrared band. The entire contents of the above-mentioned patent are incorporated herein and deemed part of the present disclosure.

Continuing the previous research, an embodiment of the present invention fabricates a planar photodetector, in which the semiconductor substrate is an n-type silicon substrate, the metal layer is made of silver, the positive finger-shaped electrode that contacts with the metal layer is made of silver, and the back electrode that ohmic contacts with the silicon substrate is made of aluminum. In addition, another photodetector is produced with the above same materials and configuration as the planar photodetector except that an inverted pyramid structure (IPS) array with a period of 16 m is further formed on the surface of the silicon substrate.

Next, light-emitting diodes (LEDs) with various emitting center wavelengths are used as light sources. The photodetector to be measured is connected to a multi-function power meter (Keithley 2400) and placed 11 cm away from the light source. LabView software is employed to readout the response current. In addition, a chopper is arranged 9 cm away from the light source and is switched on and off at a frequency of 5 seconds on and 5 seconds off. Finally, a black box covered with black cloth is used to cover the entire measurement system, so as to block the influence of environment light. Before measurement, use a power meter to measure the incident power of the LEDs at the location where the photodetector is placed. Table 1 lists the measurement results of the fabricated planar photodetector for the visible band. Table 2 lists the measurement results of the fabricated IPS photodetector (inverted pyramid structure array with period of 16 μm formed on the silicon surface) for the visible band. In this article, all photodetectors adopt the same measurement system to test the performance except for otherwise described differences (such as different light sources).

TABLE 1

| | | | | | |
|---|---|---|---|---|---|
| Incident | 420 | 460 | 530 | 580 | 630 |
| wavelength (nm) | | | | | |
| Response | 0.118 | 0.148 | 0.038 | 0.005 | 0.018 |
| current(mw) | | | | | |
| Responsivity | 0.124 | 0.155 | 0.069 | 0.025 | 0.035 |
| (mA/mW) | | | | | |
| EQE(%) | 1.01 | 0.95 | 0.79 | 0.89 | 1.14 |

TABLE 2

| | | | | | |
|---|---|---|---|---|---|
| Incident wavelength | 420 | 460 | 530 | 580 | 630 |
| (nm) | | | | | |
| Response current | 0.374 | 0.246 | 0.148 | 0.151 | 0.215 |
| (mw) | | | | | |
| Responsivity | 0.342 | 0.358 | 0.341 | 0.423 | 0.584 |
| (mA/mW) | | | | | |
| EQE(%) | 36.31 | 41.44 | 16.01 | 5.30 | 6.83 |

From Table 1 and Table 2, the response currents of the planar and IPS photodetectors gradually decrease as the incident wavelength increases in the visible band. The intrinsic silicon property is dominated in the visible band. In addition, because the surface plasmon energy of planar photodetectors is in the form of free space, it cannot effectively enhance the carriers of the photodetector with low light absorption efficiency, resulting in low external quantum efficiency (EQE). By contrast, the IPS photodetector effectively confines the incident light in the inverted pyramid structures to result in resonances. Such that more carriers obtain a higher energy, leading to a higher response current and hence a higher external quantum efficiency.

In addition, from 500 nm to 2500 nm the transmission and reflection spectra of the two produced photodetectors were measured, and the corresponding absorption spectra were calculated. Compared with photodetectors with inverted pyramid structure array on the silicon surface, the reflection of planar photodetectors is much higher. In addition, the planar photodetector has poor transmittance and low absorption. The IPS photodetector absorbs part of the near-infrared light and transmits part of the near-infrared light.

Based on the above experimental results, the responsivity of the photodetector with the inverted pyramid structure array on the semiconductor surface is still insufficient for infrared light with longer wavelengths. One of the objectives of the present invention is to propose a new photodetector to solve the above problem.

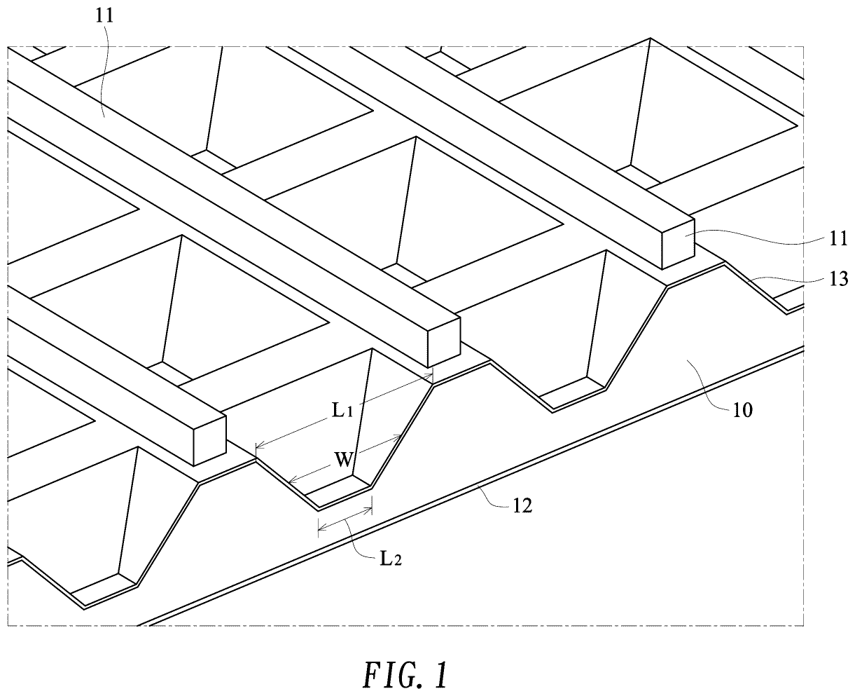

FIG. 1 shows a photodetector 1 according to an embodiment of the present invention. Referring to FIG. 1, the photodetector includes a semiconductor layer 10, a metal layer 13, a first electrode 11, and a second electrode 12. An inverted truncated-pyramid structure array (ITPS) is formed on the surface of the semiconductor layer 10 by an appropriate manner, such as but not limited to, dry etching or wet etching, and the cross-section of each inverted truncated-pyramid structure includes an upper base and a lower base. The dimensions (length) of the upper and lower base are L1 and L2 respectively, where L1 is greater than L2. In addition, the cavity length (or cavity width) W of the inverted truncated-pyramid structure gradually increases from L2 to L1, inducing localized surface plasmon resonances (LSPR) in the inverted truncated-pyramid structure corresponding to different wavelengths of the incident light. The lower surface of the metal layer 13 forms Schottky contact with at least part of the surface of the inverted truncated-pyramid structure array. The first electrode 11 is in contact with the upper surface of the metal layer 13. The second electrode 12 forms an ohmic contact with the rear surface of the semiconductor layer 10. The carriers in the metal layer 13 or the semiconductor layer 10 are excited by the incident photons and form hot carriers crossing the interface between the metal layer and the semiconductor layer, thereby generating a photocurrent. It is not necessary to have the first electrode 11 above every two adjacent inverted truncated-pyramid structures; the spacing between these mutually connected finger-shaped electrodes can be larger.

### Example of Producing the Photodetector Shown in FIG. 1:

In order to compare with the fabricated IPS photodetector (with an inverted pyramid array on the silicon surface), the ITPS photodetector (with an inverted truncated-pyramid structure array on the silicon surface) is made of the same materials as the IPS photodetector. And the materials are not limited thereto. A double-sided polished n-type silicon wafer (100) with a thickness of 600 μm˜610 μm, a resistivity of 2˜7 (Ω-cm), and a doped phosphorus atomic concentration of 7×10¹⁴ cm⁻³, is used as the semiconductor layer. At room temperature, its Fermi level (EF) is −4.32 eV. Silver with a work function less than 4.32 eV is selected as the metal layer. Due to differences in crystalline phases arrangement, its work function is approximately between 4.26 and 4.74 eV. Aluminum is selected as the material of the second electrode, whose work function is 4.08 eV, and it can generate ohmic contact with the silicon substrate.

The detail of the fabrication is as follows:
(1) Use a diamond knife to cut the n-type silicon substrate into 2.5 cm×2.5 cm square pieces. Wash the silicon substrate with acetone, isopropanol (IPA), and deionized water in sequence for 10 minutes each. Then use a nitrogen gun to dry the surface of silicon substrate.
(2) Employ a plasma enhanced chemical vapor deposition (PECVD) to deposit silicon dioxide (SiO²) with a thickness of 600 nm on the upper and lower surfaces of the silicon substrate as a mask and a protective layer for subsequent steps.
(3) Clean the silicon substrate again according to the procedure recited in step (1). The cleaned silicon substrate is placed in an oven and dried at 100° C. to remove residual moisture.
(4) Use a spin-coater to coat hexamethyldisilazane (HMDS) on the surface of silicon substrate with an initial speed/duration 1000 rpm/10 seconds and a final speed/duration of 4000 rpm/20 seconds. The coated HMDS is used to change the polarity of the silicon surface and increase the adhesion between photoresist and silicon.
(5) Then use the spin coater to coat a negative photoresist S1813 with an initial speed/duration of 1000 rpm/10 seconds and a final speed/duration of 4000 rpm/20 seconds.
(6) Place the silicon substrate on a hot plate for soft baking at 120° C. for 3 minutes after spin-coated with HMDS and negative photoresist. During the baking, the water contained in the photoresist decreases and the adhesion to the silicon substrate increases.
(7) Use an exposure machine to perform yellow light lithography. Select a photomask with the desired array dimensions and clean its surface with acetone and isopropyl alcohol. Arrange the photomask and the silicon substrate in the exposure machine and exposure the silicon substrate for 25 seconds. Remove the silicon substrate and perform post-exposure baking using the hot plate at 120° C. to reduce the water content in the photoresist.
(8) Develop the cooled sample with MF-319 developer and shake it gently for a few times during the development with development period about 35 seconds. After development, the silicon substrate was washed with deionized water and dried with a nitrogen spray gun, and finally its pattern was examined with a microscope.
(9) Place the exposed and developed sample on the hot plate and bake it for three minutes at 130° C. to minimize the moisture in the photoresist and completely solidify the photoresist on the silicon substrate.
(10) Anisotropic dry etching the silicon dioxide and silicon by a reactive ion etching system with the gases and parameters listed below.
SiO₂: CHIF₃ (30 sccm), Pressure: 1.3 Pa, RF Power: 90 W, Etching time 30 minutes;
Si: CHF₄ (30 sccm), O₂ (10 sccm), Pressure: 1.3 Pa, RF Power: 250 W, Etching time 13 minutes;
(11) Next, prepare a potassium hydroxide (KOH) solution for wet etching. Add 100 ml of KOH solution with a weight concentration of 45 wt % to 80 ml of deionized water. After mixing, heat the solution to 75° C. The concentration of KOH solution is different from that to fabricate inverted pyramid structures, a high-concentration etching solution must be used to create inverted truncated-pyramid structure with a flat surface at the bottom. Soak the sample into the KOH solution for wet etching about 4 minutes and an inverted truncated-pyramid structure array with a period of 14 μm can be made. Use a microscope to observe the etching process to avoid over-etching.
(12) After the wet etching is completed, soak the silicon substrate in a silicon dioxide etching solution (Buffered Oxide Etchant, BOE) for five minutes and then take it out to remove the remaining mask and protective layer.
(13) Use a thermal evaporator to deposit 10 nm thick silver on upper surface of the silicon substrate as the metal layer (active layer) of the photodetector, with an evaporation rate of 0.1 Å/s.
(14) Use the thermal evaporator and a mask to evaporate 100 nm-thick finger-shaped silver electrode on the metal layer, with an initial evaporation rate of 0.1 Å/s to deposit 10 nm, then 0.3 Å/s to deposit 10 nm, 0.5 Å/s to deposit 10 nm, 0.7 Å/s to deposit 10 nm, and finally 1 Å/s to deposit the thickness to 100 nm.
(15) Finally, use the thermal evaporator to deposit 100 nm-thick metallic aluminum on the rear surface of the silicon substrate as the back electrode for ohmic contact. The evaporation rates are same as that of the finger-shaped silver electrode.

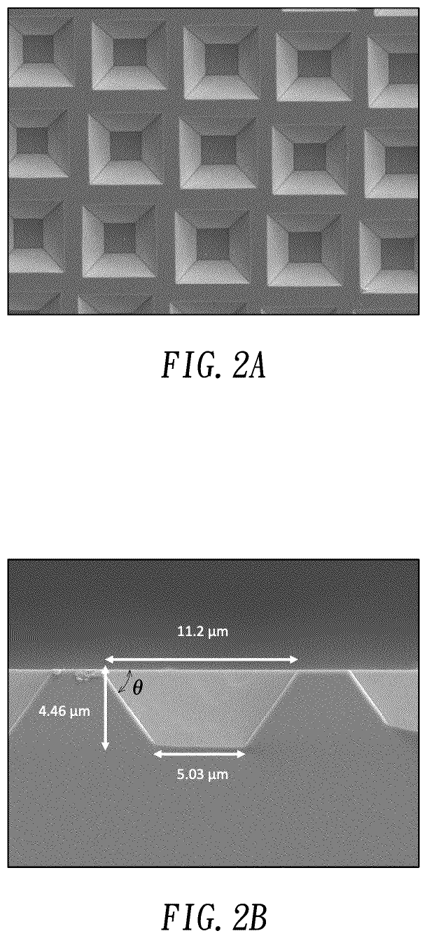

The fabricated inverted truncated-pyramid structure (ITPS) array was observed with a scanning electron microscope (SEM). FIGS. 2A and 2B are SEM images showing top and side view of the fabricated ITPS array, respectively. From the SEM image, the angle θ of the trapezoid etched by KOH is 55.37°. In addition, the etching time is also adjusted to produce another photodetector with an inverted pyramid structure (IPS) array on the silicon surface. It can be observed from experiments that a mask with a period of 14 μm can produce inverted pyramid structures with a base of 13.5 μm, or produce an inverted truncated-pyramid structure with an upper base of 11.5 μm. Therefore, it is necessary to use photomasks with different period to create an inverted pyramid structure array and an inverted truncated-pyramid structure array with the same period (i.e., the (lower) base of the IPS=the upper base of the ITPS).

The I-V curves of the photodetector with the inverted pyramid structure array and the photodetector with the inverted truncated-pyramid structure array on the silicon surface were measured respectively. It can be observed from the I-V curve that there is not much difference in the electrical properties of the two, and the leakage current is also similar.

The photodetectors with IPS and ITPS array on the silicon surface are tested using the measurement system previously described in this article, in which the blackbody radiation generated by heating the ceramic through direct current is used as the light source. In addition, a bandpass filter, which passes a wavelength band with center wavelength 3.46 μm, 4.26 μm, or 5.3 μm, is arranged between the photodetector and the light source. Table 3 lists the response currents (nA) of the IPS and ITPS photodetector.

TABLE 3

| | IPS(14 μm) | | | ITPS(11 μm/5 μm) | | |
|---|---|---|---|---|---|---|
| | photodetector -response | | | photodetector -response | | |
| | current(nA) | | | current(nA) | | |
| Temprature | 3.46 μm | 4.26 μm | 5.3 μm | 3.46 μm | 4.26 μm | 5.3 μm |
| 350° C. | 1.18 | 0.63 | — | 0.50 | 0.80 | 0.81 |
| 330° C. | 0.94 | 1.18 | — | 0.23 | 0.76 | — |
| 310° C. | 0.39 | 0.51 | — | 0.12 | 0.60 | — |
| 290° C. | 0.25 | 0.22 | — | — | 0.18 | — |
| 270° C. | — | — | — | — | 0.14 | — |
| 250° C. | — | — | — | — | — | — |

As shown in Table 3, the ceramic is heated between 250° C. to 350° C. The higher the temperature, the higher the light intensity. The IPS photodetector can detect light passing through the 3.46 μm and 4.26 μm filters, but it cannot detect light passing through the 5.3 μm filter. The ITPS photodetector can detect all three wavebands. In particular, when the central wavelength of the incident light is close to the length of the lower base of ITPS, the photodetector reveals a certain response current regardless of the intensities of the incident light.

Next, a photodetector with an inverted pyramid structure (IPS) array and a photodetector with an inverted pyramid structure (ITPS) array on the silicon surface are fabricated using two masks with different periods. The length of the base of the IPS is 14 μm, which is equal to the length of the upper base of ITPS (14 μm). The fabricated two photodetectors are tested using the measurement system described previously in this article, in which an incandescent lamp applied with various input voltages is used as the light source, and a passband filter 3.46 μm, 4.26 μm, 5.3 m, 6.0 μm, or 7.0 μm is set between the photodetector and the light source. Before measurements, the incident powers under different input voltages were measured at the position that the photodetector is arranged.

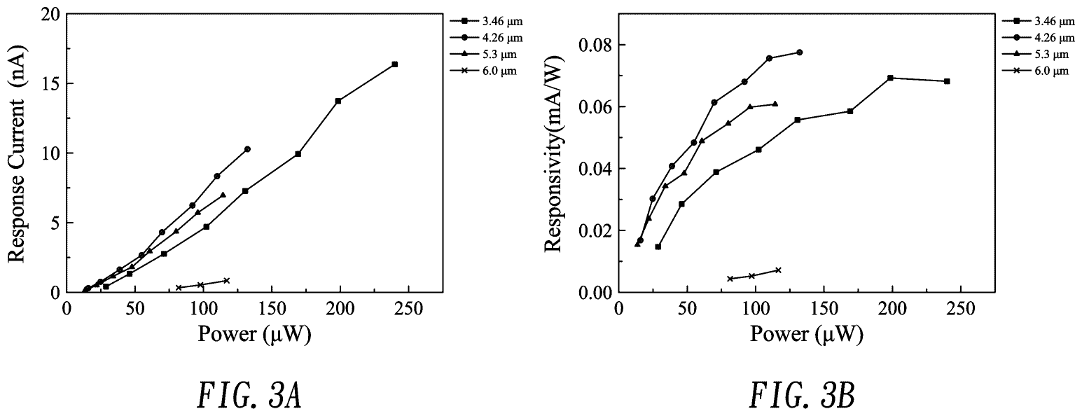

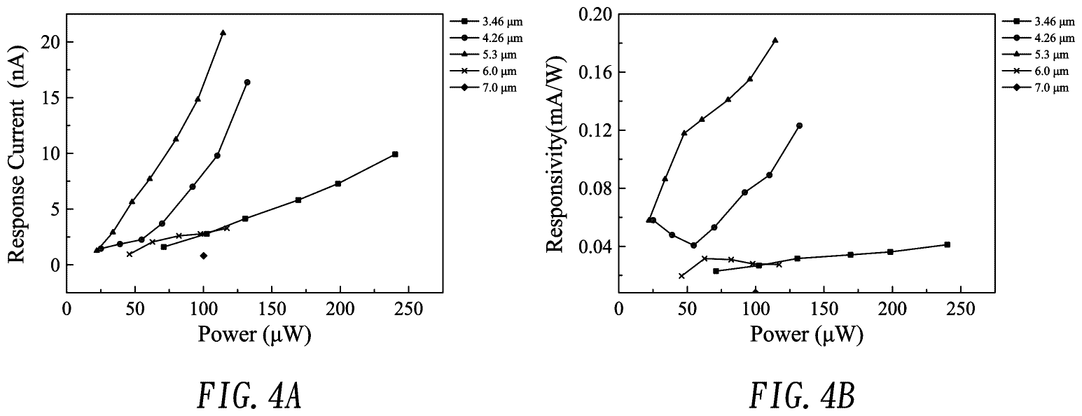

FIG. 3A and FIG. 3B show the relationship between incident power and response current/responsivity of the fabricated photodetector having IPS (the length of base=14 μm) on the silicon surface, and the measurements are made with different bandpass filters 3.46, 4.26, 5.3, 6.0 m between and the incident light and the photodetector. FIG. 4A and FIG. 4B show the relationship between incident power and response current/responsivity of the fabricated photodetector having ITPS (upper base 14 μm/lower base 5 μm) on the silicon surface, and the measurements are made with different bandpass filters 3.46, 4.26, 5.3, 6.0 μm between and the incident light and the photodetector.

It can be observed from FIGS. 4A and 4B that the photodetector with ITPS reveals different response currents in response to incident light with different wavelengths. As the central wavelength of the incident light is close to the length of the lower base of the ITPS, a best response current and responsivity are observed. It can be observed from FIGS. 3A and 3B that the photodetector with IPS has the highest response current responsive to short-wavelength incident light. As the wavelength of the incident light increases, the response current gradually decreases.

In addition, a measurement same as FIG. 3A is performed to compare a photodetector having IPS (base length/period 14 μm) and another photodetector having IPS (base length/period 16 μm), where the incandescent lamp is applied with a constant voltage of 30V. Compared with IPS (14 μm) photodector, the IPS (16 μm) photodector generally reveals a higher response current and is capable of detecting incident light with longer wavelengths.

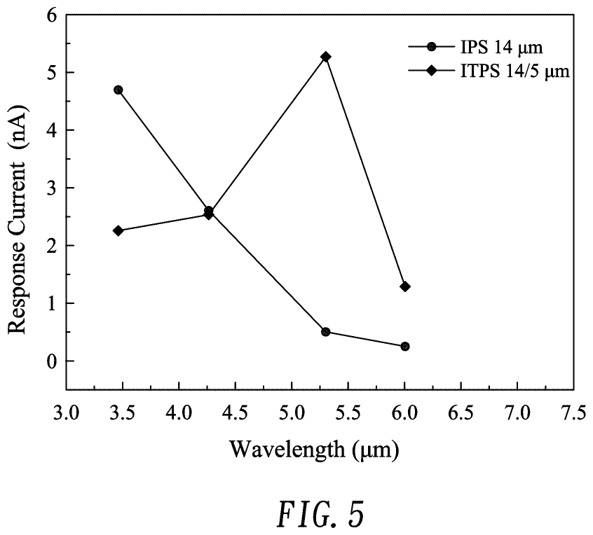

FIG. 5 shows the relationship between the wavelengths of incident light and the response currents of a photodetector having IPS (with a period/base 14 μm) and a photodetector having ITPS (with period/upper base 14 μm and lower base 5 μm), where the incident light is emitted from an incandescent lamp applied with a constant voltage of 30V. It can be observed from FIG. 5 that as the central wavelength of the incident light is close to the length of the lower base of the ITPS, the response current of the ITPS photodetector is higher than that of other incident wavelengths. In addition, because the bottom of ITPS has removed a portion where short wavelengths can resonate, the response current is smaller than that of the IPS photodetector when a 3.46 μm bandpass filter is used. The response current of the IPS photodetector gradually decrease as the wavelength of incident light increases. It is speculated that the positions of IPS that longer wavelengths induce resonances are near the surface of the photodetector, and hence the resonances are easily affected by the external environment.

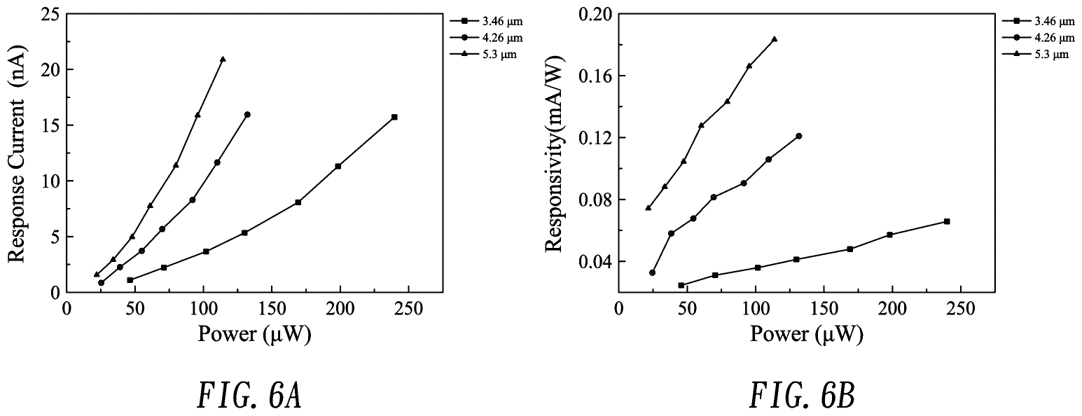

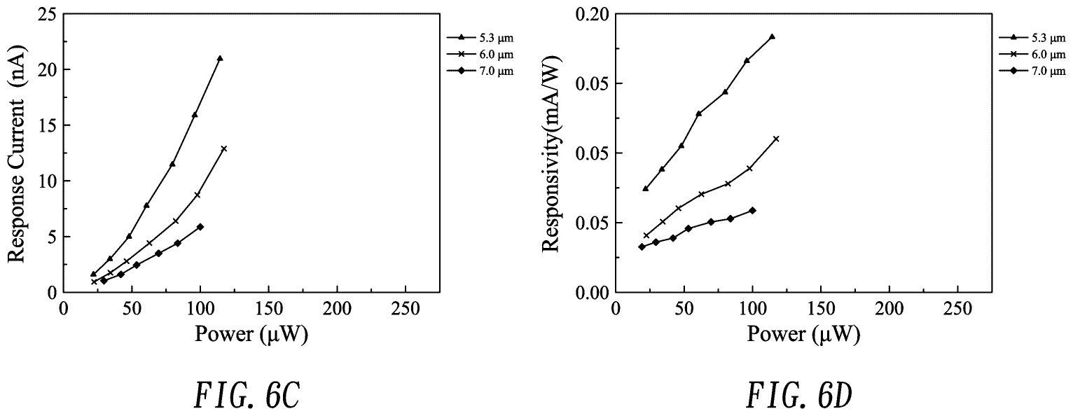

FIGS. 6A and 6B show the incident power versus response current/responsivity of the photodetector with ITPS (upper base 16 μm/lower base 5 μm) on the silicon surface, and the measurements are made with different bandpass filters (3.46 μm, 4.26 μm, 5.3 μm) between and the incident light and the photodetector. FIGS. 6C and 6D show the incident power versus response current/responsivity of the photodetector with ITPS (upper base 16 μm/lower base 5 μm) on the silicon surface, and the measurements are made with different filters (5.3 μm, 6.0 μm, 7.0 μm) between and the incident light and the photodetector. Similar to the results of FIGS. 4A and 4B, it can be observed from FIGS. 6A to 6D that the ITPS photodetector reveals different response currents for incident light with different wavelengths. As the central wavelength of the incident light is close to the length of the lower base of ITPS, a best response current and responsivity are observed.

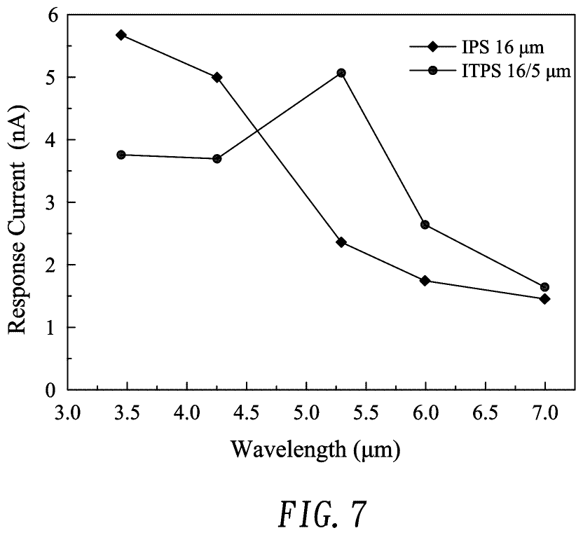

FIG. 7 shows the relationship between the wavelengths of incident light and the response currents of a photodetector having IPS (with a period/lower base 16 μm) and a photodetector having ITPS (with period/upper base 16 μm and lower base 5 μm), where the incident light is emitted from an incandescent lamp applied with a constant voltage of 30V. The results in FIG. 7 are similar to those in FIG. 5. As the central wavelength of the incident light is close to the length of the lower base of the ITPS, the response current of the ITPS photodetector is higher than that for other wavelengths. In addition, because the bottom of ITPS has removed a portion where short wavelengths can resonate, the response current is smaller than that of the IPS photodetector when a 3.46 μm bandpass filter is used.

Table 4 lists response currents (nA) of three ITPS photodetectors with different lengths of upper base (14 μm, 11 μm, 16 μm) and a same length of lower base (5 μm). The measurements are made using different incident wavelengths and the same measurement system with an incandescent lamp applied a constant voltage 30V.

TABLE 4

| | | | | |
|---|---|---|---|---|
| ITPS | Upper | 14 | 11 | 16 |
| | base(μm) | | | |
| | Lower | 5 | 5 | 5 |
| | base(μm) | | | |
| Incident | 3.46 μm | 2.75 nA | 2.59 nA | 3.68 nA |
| wavelength | 4.26 μm | 2.44 nA | 2.01 nA | 3.72 nA |
| | 5.30 μm | 5.63 nA | 2.47 nA | 5.01 nA |
| | 6.0 μm | 0.92 nA | 1.18 nA | 2.77 nA |
| | 7.0 μm | | | 1.63 nA |

Table 5 lists response currents (nA) of three ITPS photodetectors with a same length of upper base (14 μm) and different lengths of lower base (5 μm, 6 μm, 7 μm). The measurements are made under different incident wavelengths and the same measurement system with an incandescent lamp applied a constant voltage 30V. The response current of IPS photodetector with a period (base) of 14 μm is also listed for comparison.

TABLE 5

| ITPS | Upper base | 14 | | | |
|---|---|---|---|---|---|
| | (μm) | | | | |
| | Lower base | IPS | 5 | 6 | 7 |
| | (μm) | | | | |
| Incident | 3.46 μm | 4.61 nA | 2.26 nA | 3.56 nA | 3.214 nA |
| wavelength | 4.26 μm | 2.58 nA | 2.54 nA | 2.57 nA | 2.15 nA |
| | 5.30 μm | 1.86 nA | 5.26 nA | 2.28 nA | 2.17 nA |
| | 6.0 μm | 0.32 nA | 1.30 nA | 2.07 nA | 2.95 nA |
| | 7.0 μm | — | — | | 1.81 nA |

The data in Tables 4 and 5 show that, in addition to the length of the lower base, the ratio of the upper and lower bases of the ITPS may also affect the surface plasmon resonance, thereby affecting the response current. Among them, the photodetector with an upper/lower base ratio of 14/5 μm reveals the strongest resonance and wavelength-selective effect.

The measurements that the blackbody radiation by heating ceramic as the incident light lead to three conclusions. First, the ITPS cause a change in the electric field intensity distribution of localized surface plasmon resonance, such that the ITPS photodetector can detect longer wavelength bands than the IPS photodetector. Second, although the power of incident light decreases at low heating temperatures, the ITPS photodetectors still reveal good response currents. Third, the ITPS photodetectors are wavelength-selective, and their response currents to incident light with shorter wavelengths are lower than that of IPS photodetectors.

The measurements that employs an incandescent lamp as a light source show that the ITPS photodetector (upper base 14 μm) also raises the response current for incident light with a specific wavelength. For short-wavelength incident light, the response current of the ITPS photodetector is not as good as that of the IPS photodetector. The ITPS photodetectors can detect long-wavelength infrared light, while IPS photodetectors is not so good for the same wavelength band. In addition, regardless the type of photodetector (IPS or ITPS), as the length of upper base (ITPS) or base (IPS) increases from 14 μm to 16 μm, the response current also increases.

Next, in order to confirm whether the measurement system is affected by noise, a phase-locked measurement system is used to perform further measurements. The phase-locked measurement system can effectively remove the influence of noise in the environment. The difference between the phase-locked measurement system and the previous measurement system is that a lock-in amplifier is arranged between the photodetector to be measured and the multi-function power meter (Keithley 2400), and the lock-in amplifier is also connected to a chopper controller. The lock-in amplifier used in the measurements is the SR830 lock-in amplifier produced by Stanford Research System.

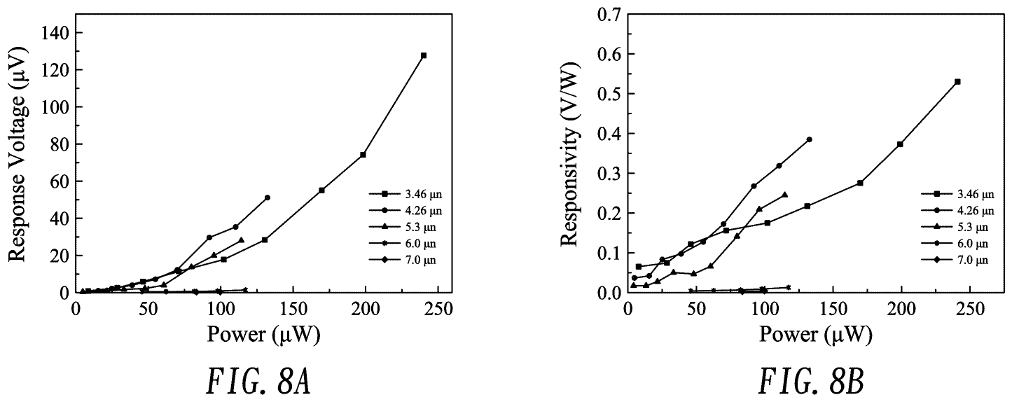

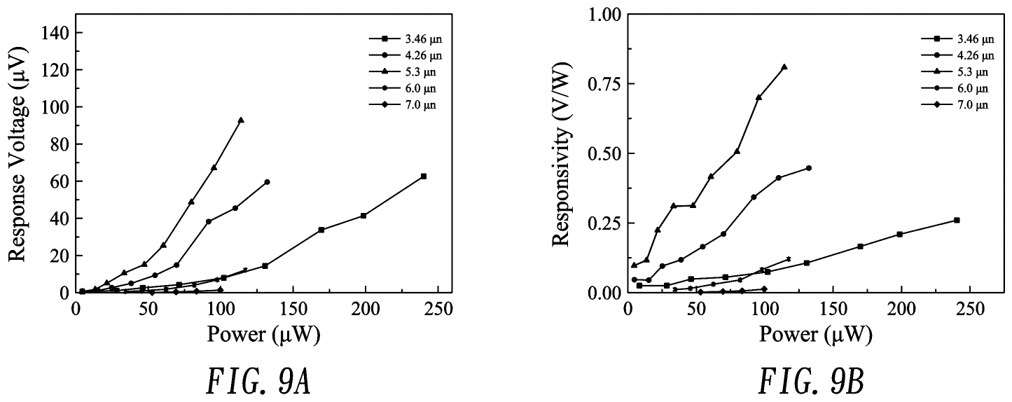

FIG. 8A and FIG. 8B show the relationship between incident power and response voltage/responsivity of the fabricated photodetector having IPS (base 14 μm) on the silicon surface, and the response voltages/responsivities are measured by the phase-locked system with an incandescent lamp as the light source and different filters (3.46, 4.26, 5.3, 6.0, 7.0 μm) between and the incident light and the photodetector. FIG. 9A and FIG. 9B show the relationship between incident power and response voltage/responsivity of the fabricated photodetector having ITPS (upper base 14 μm/lower base 5 μm) on the silicon surface, and the response voltages/responsivities are measured by the phase-locked system with an incandescent lamp as the light source and different bandpass filters (3.46, 4.26, 5.3, 6.0, 7.0 μm) between and the incident light and the photodetector.

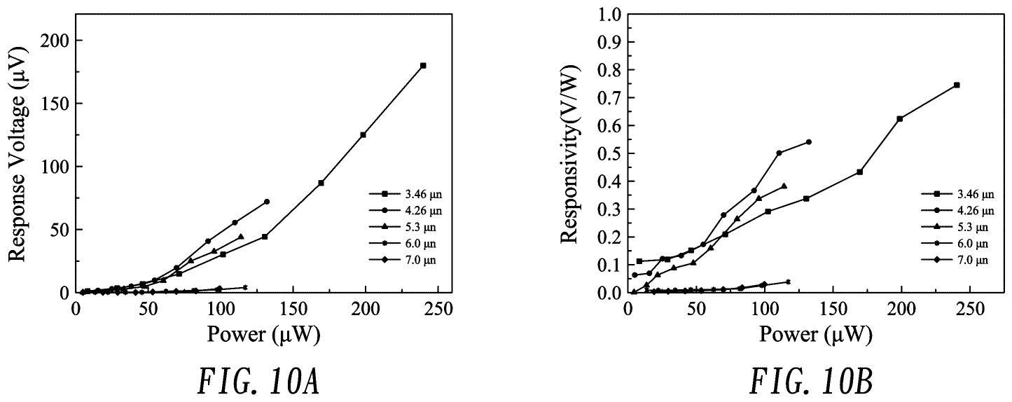

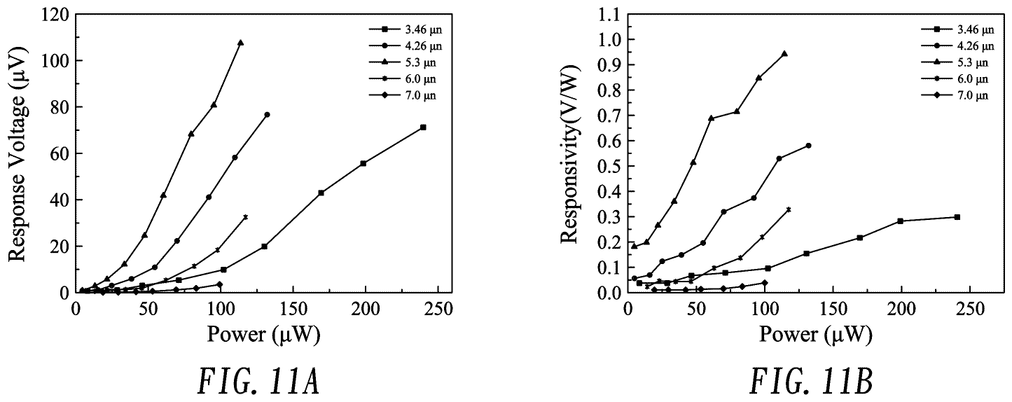

FIG. 10A and FIG. 10B show the relationship between incident power and response voltage/responsivity of the fabricated photodetector having IPS (base 16 μm) on the silicon surface, and the response voltages/responsivities are measured by the phase-locked system with an incandescent lamp as the light source and different bandpass filters (3.46, 4.26, 5.3, 6.0, 7.0 μm) between and the incident light and the photodetector. FIG. 11A and FIG. 11B show the relationship between incident power and response voltage/responsivity of the fabricated photodetector having ITPS (upper base 16 μm/lower base 5 μm) on the silicon surface, and the response voltages/responsivities are measured by the phase-locked system with an incandescent lamp as the light source and different filters (3.46, 4.26, 5.3, 6.0, 7.0 μm) between and the incident light and the photodetector.

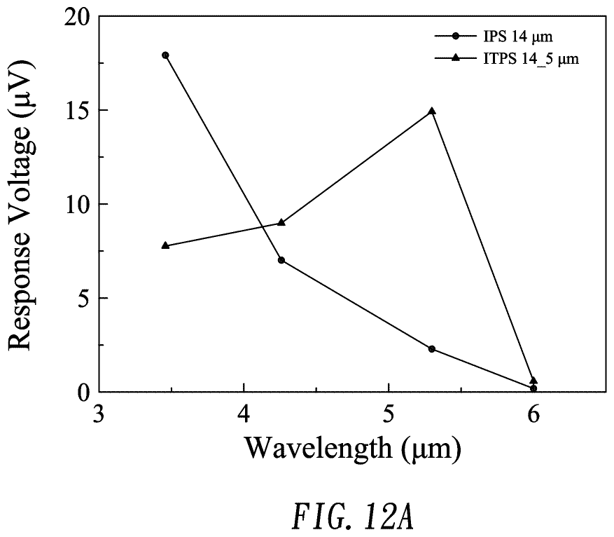

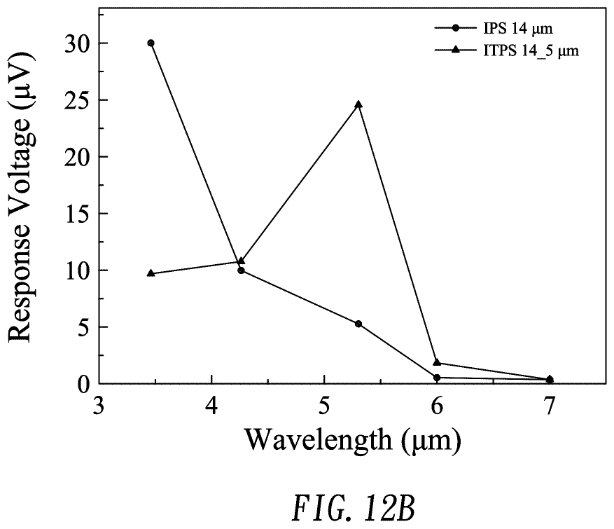

FIG. 12A shows the relationship between the wavelengths of incident light and response voltages of the photodetector having IPS (with a period/lower base 14 μm) and the photodetector having ITPS (with period/upper base 14 μm and lower base 5 μm), and the response voltages are measured by the phase-locked system with an incandescent lamp as the light source and different filters between and the incident light and the photodetector. FIG. 12B shows the relationship between the wavelengths of incident light and response voltages of the photodetector having IPS (with a period/lower base 16 μm) and the photodetector having ITPS (with period/upper base 16 m and lower base 5 μm), and the response voltages are measured by the phase-locked system with an incandescent lamp as the light source and different filters between and the incident light and the photodetector.

The results obtained from the phase-locked measurement system are similar to that of the previous measurement system. The response voltage of the IPS photodetector gradually decrease as the incident wavelength increases, while response voltage of the ITPS photodetector is wavelength selective. As the center wavelength of the incident light is close to the length of the lower base of ITPS, a strongest response voltage and responsivity can be observed. In addition, compared with the results of the previous measurement system, the measurement results obtained from the phase-locked measurement system reveal better signals for low-power incident light.

Next, a software COMSOL Multiphysics 5.6 (hereinafter referred to as COMSOL) was used to respectively simulate photodetectors with IPS and ITPS for comparing with the experimental results. The dimensions of IPS and ITPS are reduced to facilitate the simulation, where the base of IPS or the upper base of ITPS is set to 3.00 μm. The materials and thicknesses of the metal layer, semiconductor layer, and two electrodes are the same as those of the actual sample. The trapezoid angle θ of the IPS and ITPS is set to 54.7 degrees based on the characteristics of KOH wet etching. Incident light enters from the upper base. The wavelength of the incident light starts from 3.00 μm and gradually decreases to 1.6 μm with a decrement of 0.1. Then the wavelength was gradually reduced from 1.55 μm to 1.28 μm with a decrement of 0.01. The lower base of the ITPS is scaled down according to the ratio of upper base/lower base of the fabricated ITPS photodetector, as shown in Table 6.

TABLE 6

| | | | | Metal layer |
|---|---|---|---|---|
| Type | Upper base | Lower base | Ratio | thickness |
| IPS | 3.00 μm | 0 μm | / | 10 nm |
| ITPS | 3.00 μm | 1.37 μm | 0.456 | 10 nm |

Table 7 lists the maximum electric field intensities of IPS and ITPS photodetectors obtained from COMSOL for incident light with different wavelengths.

TABLE 7

| Incident | ITPS (3.00/1.38 μm) | IPS (3.00 μm) |
|---|---|---|
| wavelength (μm) | (V/m) | (V/m) |
| 3 | 2.7 | 1.46 |
| 2.9 | 2.44 | 1.39 |
| 2.8 | 2.09 | 1.24 |
| 2.7 | 1.74 | 1.19 |
| 2.6 | 2.29 | 1.17 |
| 2.5 | 2.36 | 1.33 |
| 2.4 | 2.53 | 1.36 |
| 2.3 | 2.48 | 1.43 |
| 2.2 | 2.23 | 1.45 |
| 2.1 | 1.91 | 1.36 |
| 2.0 | 2.23 | 1.46 |
| 1.9 | 2.43 | 1.56 |
| 1.8 | 2.26 | 1.72 |
| 1.7 | 2.19 | 1.75 |
| 1.6 | 2.3 | 1.59 |
| 1.55 | 2.76 | 1.66 |
| 1.54 | 2.84 | 1.67 |
| 1.53 | 2.7 | 1.7 |
| 1.52 | 2.39 | 1.71 |
| 1.51 | 2.21 | 1.7 |
| 1.5 | 2.11 | 1.72 |
| 1.49 | 2.19 | 1.68 |
| 1.48 | 2.19 | 1.65 |
| 1.47 | 2.3 | 1.59 |
| 1.46 | 2.18 | 1.58 |
| 1.45 | 2.11 | 1.54 |
| 1.44 | 2.14 | 1.8 |
| 1.43 | 2.2 | 1.72 |
| 1.42 | 2.15 | 1.72 |
| 1.41 | 2.31 | 1.7 |
| 1.4 | 2.32 | 1.54 |
| 1.38 | 2.31 | 1.55 |
| 1.37 | 2.34 | 1.49 |
| 1.36 | 2.29 | 1.42 |
| 1.35 | 2.31 | 1.56 |
| 1.34 | 2.31 | 1.65 |
| 1.33 | 2.26 | |
| 1.32 | 2.44 | |
| 1.31 | 2.54 | |
| 1.3 | 2.64 | |
| 1.29 | 2.63 | |
| 1.28 | 2.44 | |

Observed from the data in Table 7, first, as the wavelength of the incident light is 1.16 times the length of the lower base of ITPS, a maximum electric field intensity is observed. As the wavelength of the incident light is equal to the length of the upper base (i.e. period) of ITPS, a secondary strongest electric field intensity is observed. Second, the resonance induced by ITPS is greater than the resonance induced by IPS. Third, the average electric field intensity of the ITPS photodetector is greater than that of the IPS photodetector. Therefore, for photodetectors with same-period IPS or ITPS, the ITPS photodetector is capable of detecting a longer but weaker wavelength band.

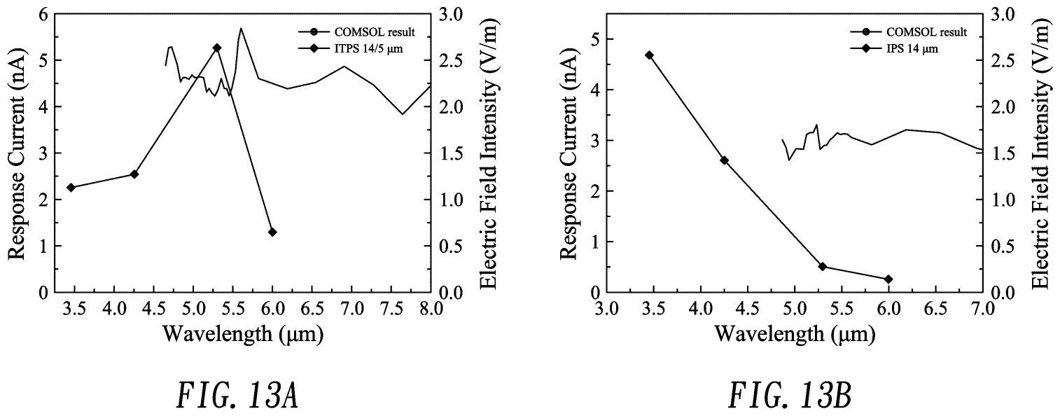

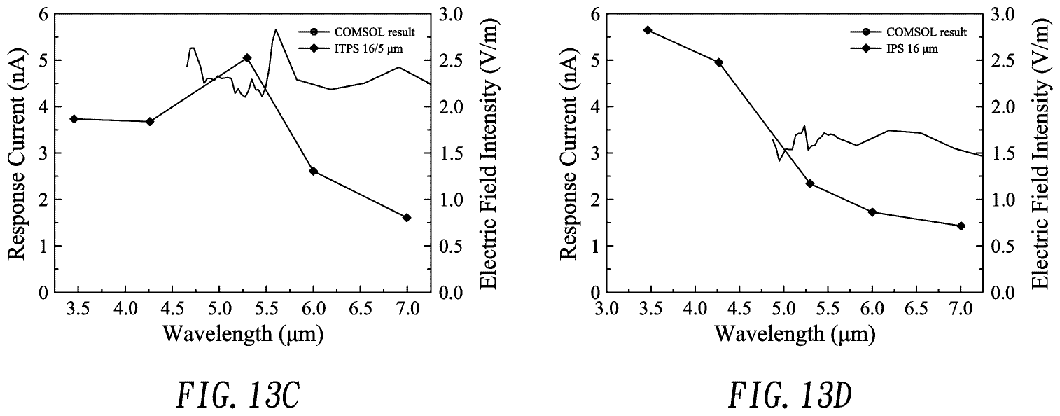

Based on the electric field intensities simulated by COMSOL, the electric field intensities of the photodetector with same dimensions equal to the fabricated photodetector can be inferred. It can be found that the maximum response current of the fabricated photodetector occurs at a wavelength that is near to the wavelength that corresponds to the maximum inferred simulated electric field intensity, as shown in FIGS. 13A to 13D. FIG. 13A and FIG. 13B respectively show the relationship between wavelengths of the incident light and the response currents/the simulated electric field intensities of the photodetector with ITPS (upper base/lower base 14/5 μm) and the photodetector with IPS (lower base 14 μm). FIG. 13C and FIG. 13D respectively show the relationship between wavelengths of the incident light and the response currents/the integrated electric field intensities of the photodetector with ITPS (upper base/lower base 16/5 μm) and the photodetector with IPS (lower base 16 μm). The simulated results and experimental results show similar trends; however, all electric field intensities should be integrated over the area to determine the contribution of the surface plasmon effect to the photodetector.

Next, the simulated electric field intensities obtained by COMSOL are integrated over the metal surface to remove resonances that do not contribute from the air. Table 8 lists the integrated electric field intensities over the metal surface by using the formula I=(cnεₛᵢE²)/2, where I denotes the electric field intensity, C denotes the light speed, εₛᵢ denotes the dielectric constant of the semiconductor (silicon in this case), and E denotes the surface electric field.

TABLE 8

| Incident | ITPS (3.00/1.38 μm) | IPS (3.00 μm) |
|---|---|---|
| wavelength (μm) | (V · m) | (V · m) |
| 3 | 1.92E−11 | 1.08E−11 |
| 2.9 | 1.30E−11 | 1.04E−11 |
| 2.8 | 9.79E−12 | 9.73E−12 |
| 2.7 | 1.16E−11 | 9.04E−12 |
| 2.6 | 1.10E−11 | 9.08E−12 |
| 2.5 | 1.22E−11 | 9.47E−12 |
| 2.4 | 1.25E−11 | 9.24E−12 |
| 2.3 | 1.19E−11 | 9.20E−12 |
| 2.2 | 9.57E−12 | 9.10E−12 |
| 2.1 | 9.71E−12 | 8.98E−12 |
| 2 | 1.06E−11 | 9.20E−12 |
| 1.9 | 1.13E−11 | 9.37E−12 |
| 1.8 | 1.29E−11 | 9.62E−12 |
| 1.7 | 1.47E−11 | 9.62E−12 |
| 1.6 | 1.56E−11 | 9.88E−12 |
| 1.55 | 1.55E−11 | 9.85E−12 |
| 1.54 | 1.53E−11 | 9.91E−12 |
| 1.53 | 1.48E−11 | 9.87E−12 |
| 1.52 | 1.46E−11 | 9.84E−12 |
| 1.51 | 1.45E−11 | 9.89E−12 |
| 1.5 | 1.46E−11 | 9.95E−12 |
| 1.49 | 1.44E−11 | 9.91E−12 |
| 1.48 | 1.39E−11 | 9.83E−12 |
| 1.47 | 1.26E−11 | 9.72E−12 |
| 1.46 | 1.18E−11 | 9.42E−12 |
| 1.45 | 1.20E−11 | 9.19E−12 |
| 1.44 | 1.24E−11 | 9.32E−12 |
| 1.43 | 1.27E−11 | 9.48E−12 |
| 1.42 | 1.30E−11 | 9.54E−12 |
| 1.41 | 1.29E−11 | 9.51E−12 |
| 1.4 | 1.23E−11 | 9.48E−12 |
| 1.38 | 1.19E−11 | 9.56E−12 |
| 1.37 | 1.16E−11 | 9.48E−12 |
| 1.36 | 1.11E−11 | 9.38E−12 |
| 1.35 | 1.06E−11 | 9.21E−12 |
| 1.34 | 1.05E−11 | 9.22E−12 |
| 1.33 | 1.10E−11 | 9.26E−12 |
| 1.32 | 1.12E−11 | 9.18E−12 |
| 1.31 | 1.13E−11 | 9.28E−12 |
| 1.3 | 1.14E−11 | 9.33E−12 |
| 1.29 | 1.13E−11 | 9.36E−12 |
| 1.28 | 1.13E−11 | 9.48E−12 |

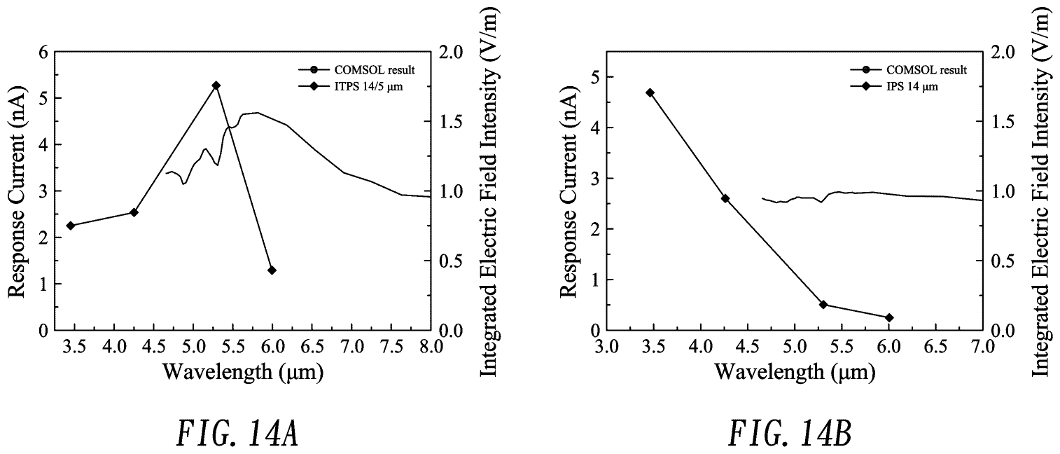

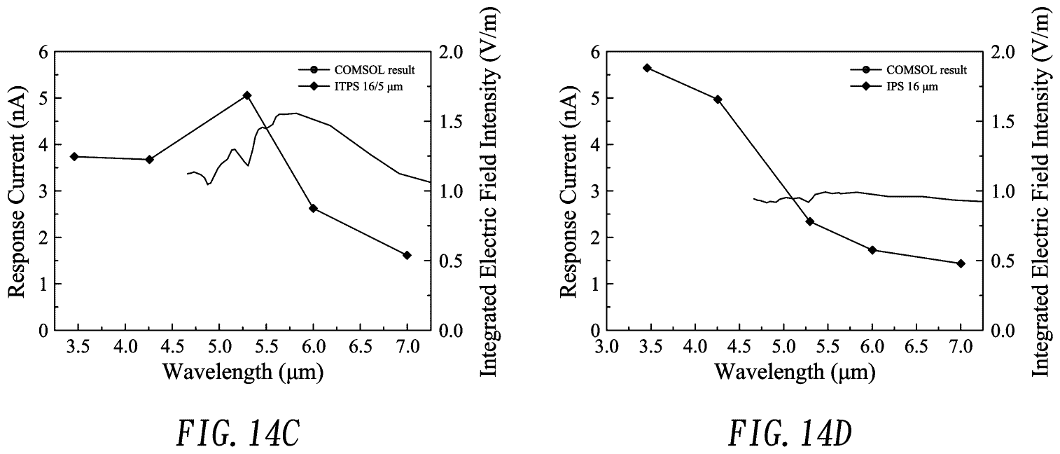

FIG. 14A and FIG. 14B respectively show the relationship between wavelengths of the incident light and the response current/the integrated simulated electric field intensity of the photodetector with ITPS (upper base/lower base 14/5 μm) and the photodetector with IPS (base 14 μm). FIG. 14C and FIG. 14D respectively show the relationship between wavelengths of the incident light and the response current/the integrated simulated electric field intensity of the photodetector with ITPS (upper base/lower base 16/5 μm) and the photodetector with IPS (base 16 μm). As shown in FIGS. 14A to 14D, the electric field intensities of the IPS photodetectors do not change much, and the electric field intensity disappears due to external influences as the resonance position moves upward. For photodetectors with ITPS, as the wavelength of the incident light approaches the length of the lower base of ITPS, the response current/electric field intensity of the photodetector is increased. The simulation results are consistent with the experimental results.

Although specific materials have been used to fabricate the exemplary photodetectors, other materials such as those described in TW Patent Application No. 107116340 and Application No. 11121205550 could also be used. For example, the metal layer may be made of gold, silver, copper, chromium, nickel, or combinations thereof.

In the exemplary embodiments, the metal layer 13 is deposited on surface of the ITPS array in a conformal manner, and hence the metal layer 13 also includes a plurality of inverted truncated-pyramid structures. Such metal layer 13 is not limited to being used in photodetectors but also be applied to other devices. In some embodiments, the metal layer 13 composed of the ITPS array can serve as a light-absorbing structure. For example, in one embodiment, a thermal insulation device includes the metal layer 13 composed of the ITPS array for absorbing infrared light and transmitting visible light. In some embodiments, the above-mentioned light absorbing structure may be fabricated by other appropriate methods, such as casting.

In some embodiments, a bottom surface of each inverted truncated-pyramid structure (ITPS) includes a lower base, and the bottom surface is hollow, that is, the bottom surface is free of the metal layer. Such configuration can be applied to the above-mentioned light absorption structure and/or each of the foregoing exemplary photodetectors.

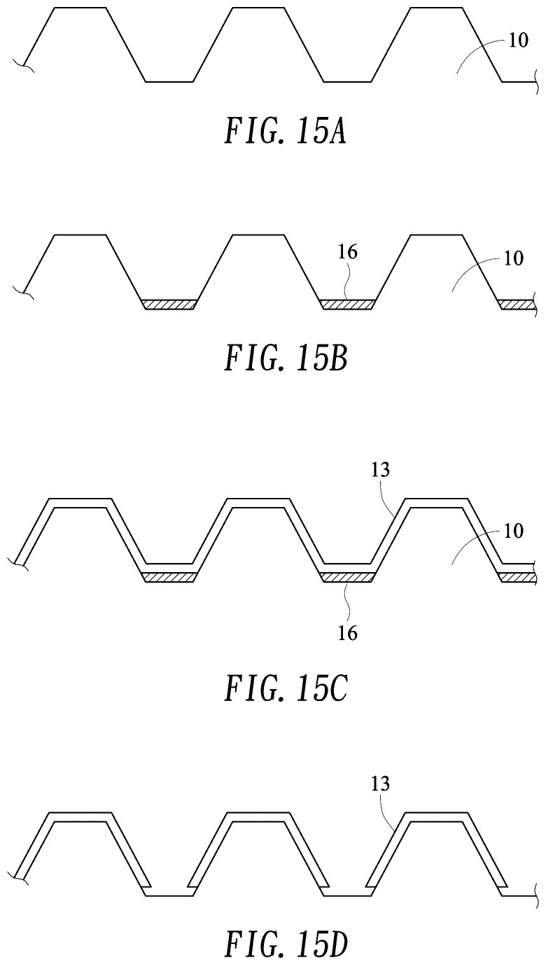

FIGS. 15A to 15D illustrate a manufacturing method wherein the bottom surface of each inverted truncated-pyramid structure is free of the metal layer. Referring to FIG. 15A, an ITPS array is formed on the surface of the semiconductor layer 10 by an appropriate method. Referring to FIG. 15B, an insulating layer 16 is deposited on the bottom surface of each inverted truncated-pyramid structure. Referring to FIG. 15C, next, a metal layer 13 is deposited on the surface of the ITPS array and the insulating layer. Referring to FIG. 15D, the insulating layer 16 and a portion of the metal layer that deposited on the insulating layer 16 are removed by a suitable manner, such as etching.

Unless otherwise indicated, all number or expressions, such as those expressing dimensions, physical characteristics, etc., used in the specification (other than the claims) are understood as modified in all instances by the term “approximately”. At the very least, and not as an attempt to limit the application of the doctrine of equivalents to the claims, each numerical parameter recited in the specification or claims which is modified by the term “approximately” should at least be construed in light of the number of recited significant digits and by applying rounding techniques.

Although the technology has been described in language that is specific to certain structures and materials, it is to be understood that the invention defined in the appended claims is not necessarily limited to the specific structures and materials described. Rather, the specific aspects are described as forms of implementing the claimed invention. Because many embodiments of the invention can be practiced without departing from the spirit and scope of the invention, the invention resides in the claims hereinafter appended.

What is claimed is:

1. A light-absorbing structure, comprising:
a metal layer composed of an inverted truncated-pyramid structure (ITPS) array to absorb an incident light;
wherein a cross-section of each inverted truncated-pyramid structure of the ITPS array comprises an upper base and a lower base, and a length of the upper base is greater than a length of the lower base.

2. The light-absorbing structure according to claim 1, wherein a thickness of the metal layer is approximately 10 nm.

3. The light-absorbing structure according to claim 1, wherein a bottom surface of each inverted truncated-pyramid structure comprises the lower base, and the bottom surface is hollow.

4. The light-absorbing structure according to claim 1, wherein a ratio of a central wavelength of the incident light to the length of the lower base is between 1.09 and 1.24.

5. The light-absorbing structure according to claim 1, wherein a ratio of the length of the upper base to the length of the lower base is between 0.312 and 0.4545.

6. The light-absorbing structure according to claim 1, wherein an absorption of the light-absorbing structure is less than 50% for the incident light in the wavelength range of 360 nm to 830 nm.

7. The light-absorbing structure according to claim 1, wherein the upper base faces the incident light.

8. A photodetector, comprising:
a semiconductor layer having an inverted truncated-pyramid structure (ITPS) array;
a metal layer forms Schottky contact with a surface of the ITPS array;
a first electrode in contact with an upper surface of the metal layer;
a second electrode forming ohmic contact with a lower surface of the semiconductor layer;
wherein a cross-section of each inverted truncated-pyramid structure of the ITPS array comprises an upper base and a lower base, and a length of the upper base is greater than a length of the lower base; and
wherein carriers in the metal layer or the semiconductor layer are excited by an incident light to form hot carriers crossing a junction between the metal layer and the semiconductor layer to generate a photocurrent.

9. The photodetector according to claim 8, wherein the photodetector is used to detect the incident light with wavelengths greater than 1.1 μm.

10. The photodetector according to claim 8, wherein a thickness of the metal layer is approximately 10 nm.

11. The photodetector according to claim 8, wherein a bottom surface of each inverted truncated-pyramid structure of the ITPS array comprises the lower base, and there is free of the metal layer above the bottom surface.

12. The photodetector according to claim 8, wherein a ratio of the central wavelength of the incident light to the length of the lower base is between 1.09 and 1.24.

13. The photodetector according to claim 8, wherein a ratio of the length of the upper base to the length of the lower base is between 0.312 and 0.4545.
